(19) United States
(12) Patent Application Publication
(10) Pub. No.: US 2024/0147680 A1
(43) Pub. Date: May 2, 2024

(54) CONDUCTIVE CONCRETE STRUCTURE FOR ELECTROMAGNETIC SHIELDING

(71) Applicant: AMERICAN UNIVERSITY OF SHARJAH, Sharjah (AE)

(72) Inventors: Sherif A. YEHIA, Sharjah (AE); Obida OTHMAN, Sharjah (AE); Nasser N. QADDOUMI, Sharjah (AE); Shereen FARHANA, Sharjah (AE); Mohamed ELCHALAKANI, Canningvale (AU)

(21) Appl. No.: 18/498,829

(22) Filed: Oct. 31, 2023

Related U.S. Application Data
(60) Provisional application No. 63/420,976, filed on Oct. 31, 2022.

(51) Int. Cl. H05K 9/00; C04B 14/48; C04B 18/14; C04B 28/00; E04B 1/92

(52) U.S. Cl. CPC H05K 9/0003; C04B 14/48; C04B 18/146; C04B 28/00; E04B 1/92; H05K 9/0086; C04B 2111/00612

(57) ABSTRACT

There is disclosed a conductive concrete structure for electromagnetic shielding comprising a first planar surface; a metal mesh positioned on a first face of the first planar surface; and cast concrete positioned on or around the metal mesh. There is also disclosed a method of assembling a conductive concrete structure for electromagnetic shielding. The method comprises positioning a metal mesh comprising a plurality of metal wires on a first planar surface and casting concrete on the metal mesh.

### CROSS-REFERENCE TO RELATED APPLICATIONS AND PRIORITY

This patent application claims priority from U.S. Provisional Application No. 63/420,976 filed Oct. 31, 2022. This patent application is herein incorporated by reference in its entirety.

### TECHNICAL FIELD

The present disclosure relates to conductive concrete structures. More particularly, but not exclusively, the present disclosure relates to conductive concrete structures for electromagnetic shielding applications.

### BACKGROUND

Background description includes information that may be useful in understanding the present disclosure. It is not an admission that any of the information provided herein is prior art or relevant to the presently claimed disclosure, or that any publication specifically or implicitly referenced is prior art.

Civil infrastructures such as electrical power systems, communications and data centers are critical for a functional smart city and must be resilient against electromagnetic pulse (EMP) events. Traditional EMP protection methods typically involve shielding and grounding with metallic structures by means of units such as—a six-sided steel panel enclosure or wire mesh Faraday cage. This approach can be costly in construction and maintenance and becomes impractical for large civil facilities.

Accordingly, there exists a need for an alternative shielding structure against electromagnetic pulses or radiations, which overcomes the drawbacks faced by traditionally employed concrete structures/units.

The present disclosure seeks to overcome at least one of the drawbacks faced by traditionally employed concrete structures/units. More specifically, but not exclusively, the present disclosure seeks to propose an improved shielding structure.

### SUMMARY

According to a first aspect of the present disclosure, there is provided a conductive concrete structure for electromagnetic shielding comprising: first planar surface; a metal mesh positioned on a first face of the first planar surface; and cast concrete positioned on or around the metal mesh.

The metal mesh positioned within the conductive concrete structure enables the structure to perform effective electromagnetic shielding. The combination of concrete and the first planar surface enables the structure to be thin and lightweight, while maintaining a high strength.

The metal mesh may be contained with the concrete. Where it is stated that the metal mesh is positioned on a first face of the first planar surface, the metal mesh may be integrated within the concrete, which is positioned on the first planar surface.

The metal mesh may comprise a plurality of metal wires.

The metal may be steel.

The concrete may comprise cement, silica fume, and fine aggregate.

The concrete may comprise 15-22% cementitious materials by volume.

The concrete may comprise 5-10% silica fume by volume.

The concrete may comprise 20-40% fine aggregate by volume.

The concrete may comprise carbon. The concrete may comprise graphite.

The concrete may comprise carbon and/or graphite. The concrete may comprise 0-30% carbon and/or graphite by volume. The concrete may comprise 10-30% carbon and/or graphite by volume.

The concrete may comprise steel fiber. The concrete may comprise 0-2% steel fiber by volume. The concrete may comprise 0.1-2% steel fiber by volume. The concrete may comprise 0.5-2% steel fiber by volume.

The inclusion of electrically conductive materials in the composition of the concrete, such as steel fiber and carbon/graphite, enhances the electrical properties of the concrete and improves the effectiveness of the electromagnetic shielding.

The volume fractions may, instead of being a volume fraction of the concrete, may be a volume fraction of the conductive concrete structure. For example, the conductive concrete structure may comprise 15-22% cementitious materials by volume.

The conductive concrete structure may comprise at least one metal wire for discharging accumulated charge connected to the metal mesh, wherein the at least one metal wire extends away from the metal mesh.

Charge buildup in the mesh through attenuation of electromagnetic interference can be effectively discharged to ground through the at least one metal wire, ensuring that the mesh continues to perform effectively as an electromagnetic shield.

The conductive concrete structure may comprise a second planar surface having a first face, wherein the first face of the second planar surface is positioned on the concrete, and wherein the at least one metal wire extends to a second face of the second planar surface.

The second planar surface may form part of the final structure when installed in a building. In embodiments, the second planar surface is a protective sheet for protecting the concrete surface during handling and transport.

The first planar surface may comprise fiberboard.

The use of fiberboard is advantageous in that it has a high strength to weight ratio and enables the manufacture of strong but thin structures. This advantageously means that the conductive concrete structure can be used as a replacement for traditionally used/commonly used gypsum boards or drywall.

The second planar surface may comprise carboard.

Cardboard provides a light and strong surface to protect the concrete surface during handling and transport.

The conductive concrete structure may provide shielding effectiveness of up to 60 dB for a frequency range 1 to 10 GHz.

The conductive concrete structure may have a compressive strength of at least 25 MPa.

The thickness of the conductive concrete structure may be between 10 mm and 50 mm.

The conductive concrete structure may be a conductive concrete wall.

The conductive concrete wall may be a thin conductive concrete wall. The term “thin” may refer to a wall thickness of 50 mm or less. The term “thin” may refer to a wall thickness of 45 mm or less, or 40 mm or less, or 35 mm or less, or 30 mm or less, or 25 mm or less.

The concrete may comprise protrusions. The protrusions may comprise any one or more of semi-spherical shapes, conical shapes, corrugations, and/or quadrilateral shapes.

The various configurations of shapes for the concrete provide multiple surfaces, increasing the surface area per unit of concrete structure, thereby improving the electromagnetic shielding efficiency of the structure.

The thickness of the conductive concrete structure excluding the protrusions is less than 20 mm.

The thickness may include both the concrete and the first planar surface (excluding the protrusions from the concrete).

According to a second aspect of the present disclosure there is provided a building comprising the conductive concrete structure of the first aspect.

The conductive concrete structure may comprise at least one metal wire for discharging accumulated charge connected to the metal mesh, wherein the at least one metal wire extends away from the metal mesh.

The at least one metal wire may be earthed.

According to a third aspect of the present disclosure, there is provided a method of assembling a conductive concrete structure for electromagnetic shielding, the method of assembling comprising: positioning a metal mesh comprising a plurality of metal wires on a first planar surface; and casting concrete on the metal mesh.

The method may comprise positioning a first face of a second planar surface on the concrete. The conductive concrete structure may comprise at least one metal wire for discharging accumulated charge connected to the metal mesh, and the method may comprise extending the at least one metal wire to a second face of the second planar surface.

Features disclosed in relation to one aspect of the present disclosure may be applicable to other aspects of the present disclosure, and vice versa.

### BRIEF DESCRIPTION OF THE DRAWINGS

The subject matter that is regarded as the present disclosure is particularly pointed out and distinctly claimed in the claims at the conclusion of the specification. The foregoing and other aspects, features, and advantages of the present disclosure are apparent from the following detailed description taken in conjunction with the accompanying drawings in which:

FIGS. 1A, 1B, 1C, and 1D show perspective views of a portion of a conductive concrete surface according to an embodiment of the present disclosure.

FIG. 2A shows a layout of drywall or a conductive concrete wall according to an embodiment of the present disclosure.

FIG. 2B shows a cross section of a thin conductive concrete wall according to an embodiment of the present disclosure.

FIG. 3 is a schematic for the thin conductive concrete assembly according to an embodiment of the present disclosure.

FIG. 4 is a schematic for a corrugated thin conductive concrete wall according to an embodiment of the present disclosure.

FIGS. 5A, 5B and 5C show a method of assembling a conductive concrete structure according to an embodiment of the present disclosure.

FIG. 6 depicts a graph showing results of a dry wall at different frequencies, according to an embodiment of the present disclosure.

FIG. 7 depicts a graph showing the results of a dry wall at different frequencies and at different temperatures, according to an embodiment of the present disclosure.

### DETAILED DESCRIPTION OF THE INVENTION

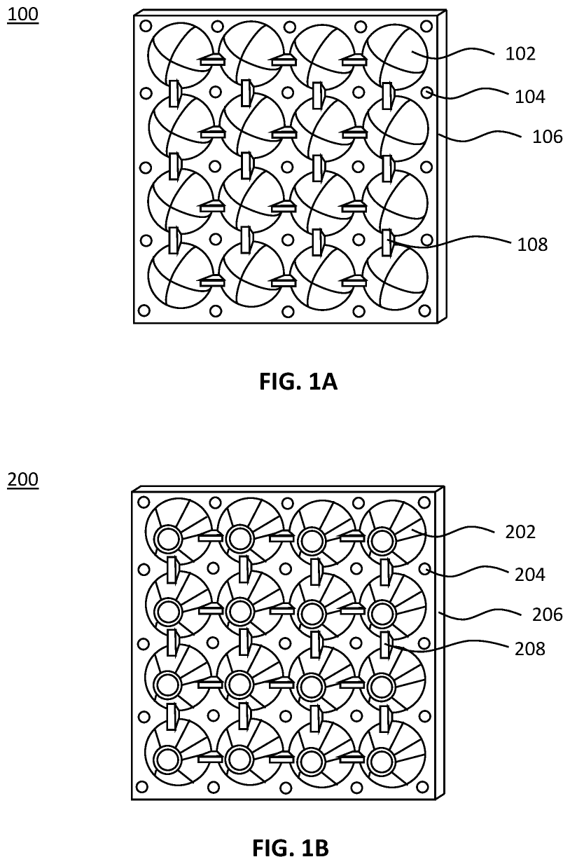

The aspects of a conductive concrete structure for shielding against electromagnetic pulses or radiations, which seeks to overcome the drawbacks faced by traditionally employed concrete structures/units, according to the present invention will be described in conjunction with FIGS. 1A-7, wherein like reference numeral denote similar like features. In the detailed description, reference is made to the accompanying figures, which form a part hereof, and in which is shown by way of illustration specific embodiments in which the invention may be practiced. It is to be understood that other embodiments may be utilized and logical changes may be made without departing from the scope of the present invention. The following detailed description, therefore, is not to be taken in a limiting sense, and the scope of the present invention is defined by the appended claims.

The present disclosure is concerned with conductive concrete structure for electromagnetic shielding applications.

Drywall is defined to be a construction material used to create walls and ceilings. It's also used to create many design features, including eaves, arches and other architectural specialties. It's quick and easy to install, incredibly durable, and requires only simple repairs when damaged. A high-performance lightweight interior wall system consisting of a GI steel frame, encased in gypsum plasterboards on either side attached with self-drilling drywall screws. The joints are then taped and finished with gypsum jointing compounds.

Embodiments of the present disclosure are suitable for use as a drywall.

FIG. 1A shows a perspective view of a portion of a conductive concrete surface 100 according to an embodiment of the present disclosure. The concrete surface 100 is cast concrete. The concrete surface 100 comprises a solid portion 106 and a plurality of protrusions 102. The protrusions 102 are in a semi-spherical shape, extending away from the surface of the solid portion 106. Bridging the gap between the protrusion 106 are supports 108. The supports 108 provide additional structural integrity to the concrete surface 100.

The concrete surface comprises indentation 104. The indentations 104 provide an additional increased surface area of the concrete surface 100, improving the electromagnetic shielding properties of the resulting structure.

The thickness of the base portion 106 is approximately 7 mm, while the thickness (depth) of the protrusions 102 are 35 mm, making the total thickness of the concrete surface 100 approximately 42 mm.

FIG. 1B shows a perspective view of a portion of a conductive concrete surface 200 according to an embodiment of the present disclosure. For conciseness, only the differences between the following figures to that of FIG. 1A will be described.

Like FIG. 1A, the conductive concrete surface 200 has a solid portion 206. The protrusions 202 are, in this embodiment, in a conical shape. The cone terminates at a flat surface towards the top of the cone.

The thickness of the base portion 206 is approximately 15 mm, while the thickness (depth) of the protrusions 202 are 35 mm, making the total thickness of the concrete surface 200 approximately 50 mm.

FIG. 1C shows a perspective view of a portion of a conductive concrete surface 300 according to an embodiment of the present disclosure.

Like FIG. 1A, the conductive concrete surface 300 has a solid portion 306. The protrusions 302 are, in this embodiment, in a quadrilateral shape. The quadrilateral extrudes outwards from the surface of the base portion 306, which is substantially flat.

The thickness of the base portion 306 is approximately 12 mm, while the thickness (depth) of the protrusions 302 are 23 mm, making the total thickness of the concrete surface 300 approximately 35 mm.

FIG. 1D shows a perspective view of a portion of a conductive concrete surface 400 according to an embodiment of the present disclosure.

Like FIG. 1A, the conductive concrete surface 400 has a solid portion 406. The protrusions 402 are, in this embodiment, a corrugated shape. In embodiments, the corrugation takes the shape of a smooth curve of alternating peaks and troughs. In embodiments, the corrugation takes the shape of a series of triangles (when viewed in cross section).

The thickness of the base portion 406 is approximately 10 mm, while the thickness (depth) of the protrusions 402 are 7 mm, making the total thickness of the concrete surface 400 approximately 17 mm.

Several configurations of the concrete surfaces with thicknesses varying from 10 mm to 50 mm are developed to improve the attenuation of electromagnetic waves. The proposed system provides shielding effectiveness of up to 60 db for a frequency range 1 to 10 GHz. The proposed technology provides a safer, sustainable alternative for existing/traditionally employed concrete structures against electromagnetic pulse events.

In embodiments, the structures are produced with a flat surface (or any surface configurations). FIGS. 1A and 1B show several samples of various thin conductive concrete wall configurations for electromagnetic shielding applications, in accordance with the present disclosure. Multiple wall configurations can be achieved, depending on the desired application, for example with a total thickness of 35 mm (12 mm solid and 23 mm extrusion), with a total thickness of 42 mm (7 mm solid and 35 mm extrusion), and with a total thickness of 50 mm (15 mm solid and 35 mm extrusion). The units are produced with varying/different thickness ranges from 10 mm to 50 mm. The unit weight of a thin conductive wall unit is comparable to that of a gypsum board with similar thickness, and the said units may be installed in new or existing structures. In addition, the proposed thin conductive concrete wall configuration may be used as adds on or as a replacement for traditionally/commonly used gypsum boards. During installation the units are connected to an electrical ground, and the said thin conductive concrete wall configuration units attenuate electromagnetic waves by reflection and any or all accumulated charges are discharged to ground. Other proposed configurations in accordance with the present invention include semi-sphere, cone, triangles etc. These configurations provide multiple surfaces which increase the attenuation of the waves and thereby improve the electromagnetic shielding efficiency of the proposed thin wall.

In addition, the proposed dry wall could be produced with thicknesses 10 mm to 50 mm which helps control the added weight to existing structures. Nine mixes were preprepared and samples using the corrugated configuration were tested to evaluate the electromagnetic interference (EMI) effectiveness. All samples were tested to evaluate the shielding effectiveness of the proposed invention. In embodiments, the system can provide attenuation up to 50 dB, which is influenced by the mix proportions and wall configuration.

In an embodiment of the present disclosure, the conductive concrete mix and proportions of the proposed thin conductive concrete wall configuration unit comprises the following materials—cement, Ground Granulated Blast-furnace Slag (GGBS), silica fume (total cementitious materials 15-22% per volume), fine aggregate (20-40% per volume), Carbon and graphite products (0-30% per volume) and steel fiber (0-2%).

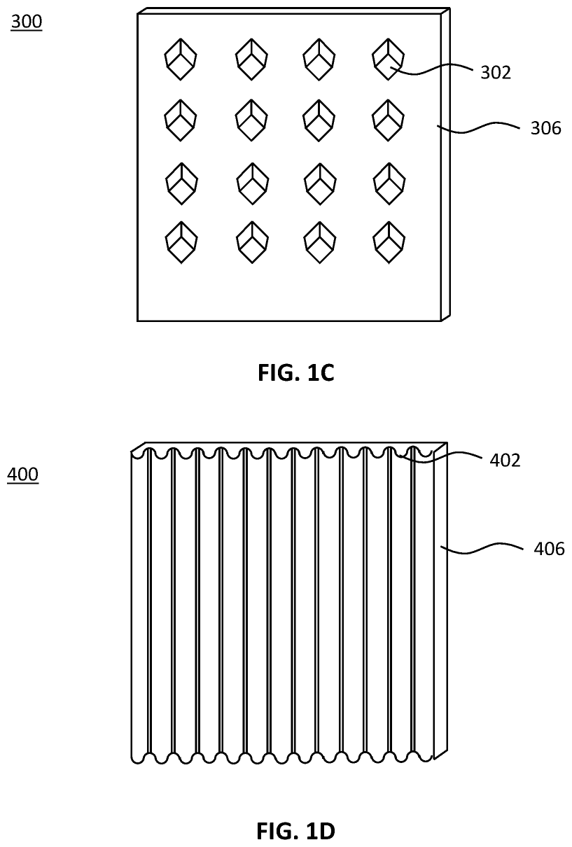

Looking to FIGS. 2A and 2B, considering the cross-section details of the proposed thin conductive concrete wall configuration unit, each unit includes a solid part 506. The thickness of the solid part or portion ranges from 10 mm to 20 mm, and a thin wire mesh 510 is placed at the middle of the solid part 506. The layout of the wire mesh is shown in FIG. 2A. Considering the mold details to prepare a prototype of the dry wall system. The total thickness is 20 mm with a solid portion/part of 13 mm. A thin steel wire is used to help discharge any charge which might accumulate on the surface. The steel wire is connected with two steel loops extended outside the back of the dry wall to help ground the wall and to discharge any accumulated charges.

FIG. 2B shows a cross section of a thin conductive concrete structure 550 according to an embodiment of the present disclosure.

The structure comprises a solid portion 554, a wire mesh 556, and a protrusion 552. In embodiments, the entire structure is formed of conductive concrete material.

In embodiments, the solid portion 554 comprises fiberboard. In embodiments, the fiberboard is medium-density fiberboard (MDF). The wire mesh 556 is, in embodiments, placed on the MDF and conductive concrete is cast on top of the mesh and the fiberboard.

In embodiments, the structure 550, wherein both the solid portion 554 and the protrusions 552 are formed of conductive concrete, is then positioned on top of a planar surface such as MDF (in such embodiments this is not shown in FIG. 2B).

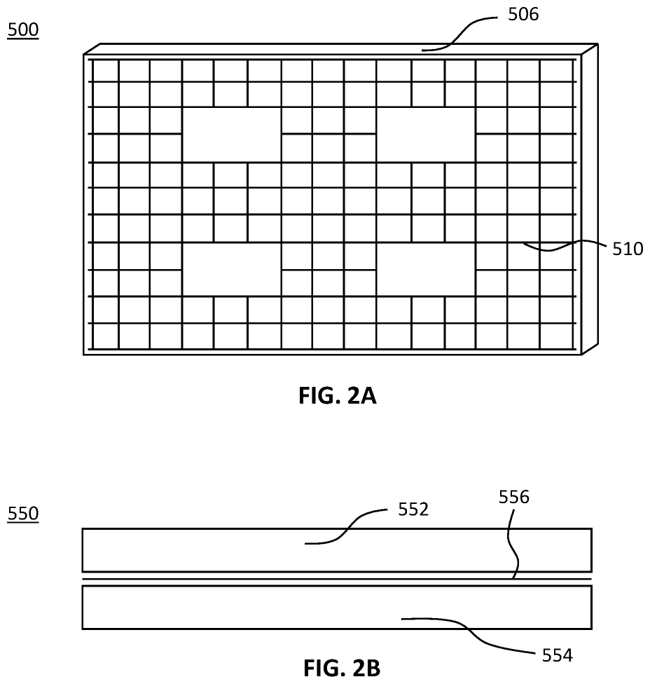

Looking to FIG. 3, metal pieces 618 are connected to the wire mesh 610 at the middle of the drywall unit and extended outside the back of the dry wall. The two metal pieces 618 are mainly connected during the construction phase to the ground, to help discharge any charge which might accumulate on the surface. Subsequently, a carboard 616 is placed after casting (as shown in FIG. 3), to provide a solid surface for shipping and handling.

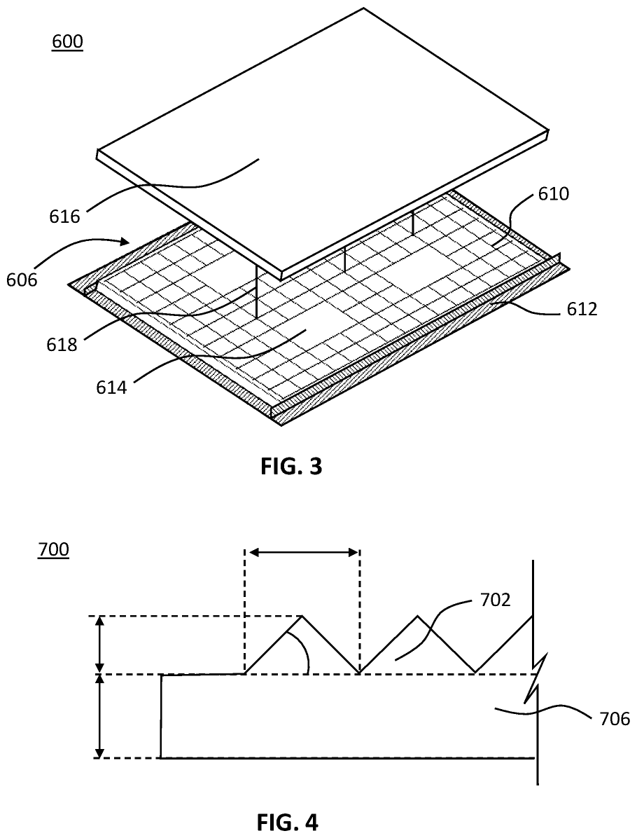

In accordance with embodiments of the present disclosure, the proposed drywall structure composition involves a new conductive mix with no coarse aggregate (fine aggregates are used in this invention), optimized to determine the % of fiber and conductive materials to be added to improve electrical properties of the drywall structure while maintaining a compressive strength more than 25 MPa. Accordingly, 2 in×2 in×2 in cubes are used to evaluate the compressive strength, and several thin slabs with corrugations and different thicknesses (10 mm, 15 mm, 20 mm) are used to evaluate the electrical properties and shielding effectiveness of each mix. The samples are then evaluated to select the optimum mix. The optimum mix is then used to produce thin walls with different configurations. FIG. 4 shows schematic for a thin conductive concrete wall according to an embodiment of the present disclosure. The solid part 706 is 10 mm in thickness and the corrugation 702 height is 7 mm with a 45° angle slope relative to the upper surface of the solid part 706.

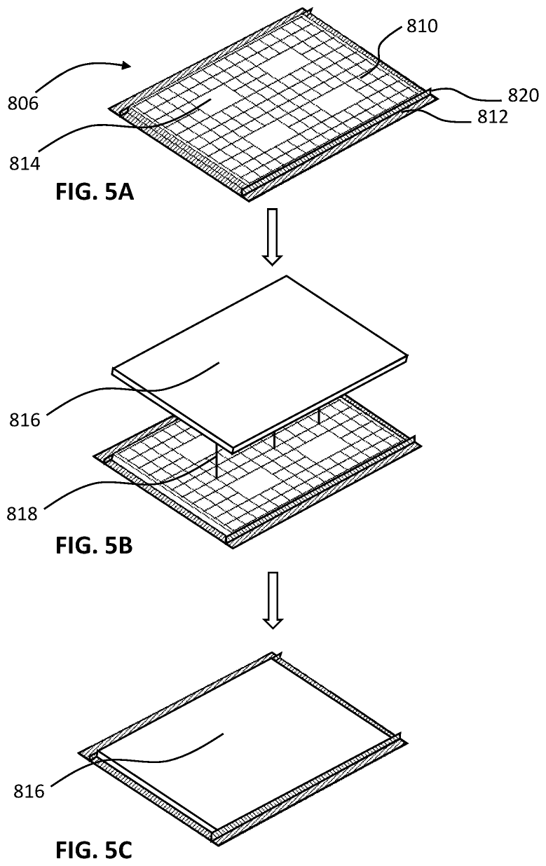

FIGS. 5A and 5B show the various components in accordance with the present invention, which when put together form the proposed thin conductive concrete wall configuration unit. The components are as follows: steel plate 812, a plate with a desired configuration such as an MDF (Medium Density Fiberboard) plate 814, a cardboard frame 820, a steel mesh 810 with earthing wires 818 and a final cardboard sheet covering 816.

FIGS. 5A, 5B, and 5C also depict a process flow of placing together the various components in accordance with an embodiment of the present disclosure, which when put together form the proposed thin conductive concrete wall configuration unit. The process includes the steps of forming the initial layers using a steel plate 812 followed by a fiber-board plate 814. On top of this initial layering, a thin wire mesh 810 is placed at the middle of the formed layers, and the conductive concrete layer 806 (not shown but the arrow indicates that the concrete is cast on top of the wire mesh 810) is cast (comprising cement, Ground Granulated Blast-furnace Slag (GGBS), silica fume (total cementitious materials 15-22% per volume), fine aggregate (20-40% per volume), etc.). A cardboard sheet 816 is placed after casting the conductive concrete layer 806. A thin wire 818 connected to the embedded wire mesh 810 is extended to the outer surface of the cardboard sheet 816, thereby completing the thin conductive concrete wall configuration unit.

In embodiments, when the concrete is cast, it is cast around the wire mesh to integrate the wire mesh within the structure of the concrete. In embodiments, the concrete is cast on top of the wire mesh such that the wire mesh is in contact with both the concrete and the first planar surface (being the MDF in embodiments of the present disclosure).

The present disclosure aims at protecting critical infrastructure facilities in smart cities, including, but not limited to, structures such as an electric grid, sensitive data centers, and vital communication channels, as this has become a growing concern globally considering that electromagnetic pulse (EMP) events continue to threaten society, business operations, and life as we know it. EMP events include high altitude electromagnetic pulses (HEMP) and intentional electromagnetic interferences (IEMI) which are easily created on utilization of high-power electromagnetic weapons to attack sensitive infrastructure assets. The present disclosure provides a cost-effective method to protect buildings and other infrastructures against EMP and is capable of being produced via different configurations and thicknesses ranges (from 10 mm to 50 mm). The proposed system provides shielding effectiveness up to 60 db for frequency ranges 1 to 10 GHz.

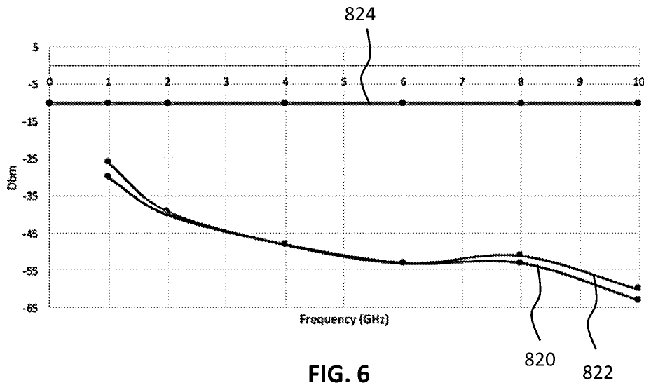

FIG. 6 shows a graph showing results of a dry wall at different frequencies, according to an embodiment of the present disclosure. The graph depicts obtained results of a 15 mm corrugated dry wall at different frequencies, in accordance with the present disclosure.

Reference line 824 shows the signal measured without any intervening media between the antennas. Reference line 824 shows the level of signal received by one antenna when the other one transmits a signal through air. This line 824 is a reference to measure the drop in the signal due to the conductive concrete indicated by lines 820 and 822 relative to the drop expected without any intervening media.

Line 820 shows the shielding effectiveness of the structure of embodiments of the present disclosure when receiving EMI from a first direction. Line 822 shows the shielding effectiveness of the structure of embodiments of the present disclosure when receiving EMI from a second direction.

As seen in the graph of FIG. 6, structures according to embodiments of the present disclosure are effective across a wide frequency range, and can provide shielding effectiveness up to 60 dB within a range of 0 to 10 GHz.

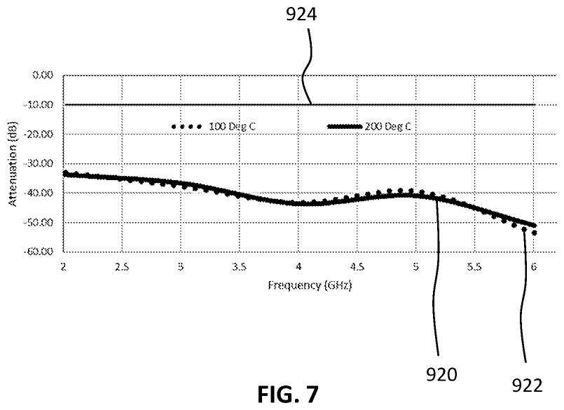

FIG. 7 depicts a graph showing the results of a dry wall at different frequencies and at different temperatures, according to an embodiment of the present disclosure. The attenuation rate of a concrete wall according to an embodiment of the present disclosure was subjected to a electromagnetic signal at varying frequencies between 2-6 GHz.

The reference line 924 is the same as the reference line 824 in FIG. 6. Line 922 shows the shielding effectiveness of the same wall as FIG. 6 at an elevated temperature of 100 Deg C. Line 920 shows the shielding effectiveness of the same wall as FIG. 6 at an elevated temperature of 200 Deg C.

The lines 920, 922 show that the effect of elevated temperature on the conductive concrete wall of embodiments of the present disclosure does not significantly affect the shielding effectiveness of the conductive concrete wall.

Many changes, modifications, variations and other uses and applications of the subject invention will become apparent to those skilled in the art after considering this specification and the accompanying drawings, which disclose the preferred embodiments thereof. All such changes, modifications, variations and other uses and applications, which do not depart from the spirit and scope of the invention, are deemed to be covered by the invention, which is to be limited only by the claims which follow.

1. A conductive concrete structure for electromagnetic shielding comprising:
first planar surface;
a metal mesh positioned on a first face of the first planar surface; and
cast concrete positioned on or around the metal mesh.

2. A conductive concrete structure according to claim 1, wherein the concrete comprises cement, silica fume, and fine aggregate.

3. A conductive concrete structure according to claim 2, wherein the concrete comprises 15-22% cementitious materials by volume.

4. A conductive concrete structure according to claim 2, wherein the concrete comprises 20-40% fine aggregate by volume.

5. A conductive concrete structure according to claim 1, wherein the conductive concrete structure comprises at least one metal wire for discharging accumulated charge connected to the metal mesh, wherein the at least one metal wire extends away from the metal mesh.

6. A conductive concrete structure according to claim 5, wherein the conductive concrete structure comprises a second planar surface having a first face, wherein the first face of the second planar surface is positioned on the concrete, and wherein the at least one metal wire extends to a second face of the second planar surface.

7. A conductive concrete structure according to claim 1, wherein the first planar surface comprises fiberboard.

8. A conductive concrete structure according to claim 6, wherein the second planar surface comprises carboard.

9. A conductive concrete structure according to claim 1, wherein the conductive concrete structure provides shielding effectiveness of up to 60 db for a frequency range 1 to 10 GHz.

10. A conductive concrete structure according to claim 1, wherein the conductive concrete structure has a compressive strength of at least 25 MPa.

11. A conductive concrete structure according to claim 1, wherein the thickness of the conductive concrete structure is between 10 mm and 50 mm.

12. A conductive concrete structure according to claim 1, wherein the conductive concrete structure is a conductive concrete wall.

13. A conductive concrete structure according to claim 1, wherein the concrete comprises protrusions.

14. A conductive concrete structure according to claim 14, wherein the protrusions comprise any one or more of semi-spherical shapes, conical shapes, corrugations, and/or quadrilateral shapes.

15. A conductive concrete structure according to claim 13, wherein the thickness of the conductive concrete structure excluding the protrusions is less than 20 mm.

16. A building comprising the conductive concrete structure of claim 1.

17. A building according to claim 16, wherein the conductive concrete structure comprises at least one metal wire for discharging accumulated charge connected to the metal mesh, wherein the at least one metal wire extends away from the metal mesh.

18. A building according to claim 17, wherein the at least one metal wire is earthed.

19. A method of assembling a conductive concrete structure for electromagnetic shielding, the method of assembling comprising:
positioning a metal mesh comprising a plurality of metal wires on a first planar surface; and
casting concrete on the metal mesh.

20. A method of assembling a conductive concrete structure according to claim 19,
wherein the method comprises positioning a first face of a second planar surface on the concrete, and
wherein the conductive concrete structure comprises at least one metal wire for discharging accumulated charge connected to the metal mesh, and the method comprises extending the at least one metal wire to a second face of the second planar surface.
